(19) United States
(12) Patent Application Publication
(10) Pub. No.: US 2026/0190292 A1
(43) Pub. Date: Jul. 2, 2026

(54) HIGH-EFFICIENCY VAPOR CHAMBER

(71) Applicant: Zhongshan Zhongde Technology Co., Ltd, Zhongshan (CN)

(72) Inventors: Cong Wu, Zhongshan (CN); Yuxiang He, Zhongshan (CN)

(21) Appl. No.: 19/065,542

(22) Filed: Feb. 27, 2025

(30) Foreign Application Priority Data
Jan. 2, 2025 (CN) 2025200081445

(51) Int. Cl. H05K 7/20

(52) U.S. Cl. CPC H05K 7/20336; H05K 7/20309; H05K 7/20318

(57) ABSTRACT

A high-efficiency vapor chamber is disclosed, including a plate body, a support column, a heat transfer medium, and a capillary guide column. The plate body defines an accommodation cavity having two heat-conducting cavity walls arranged oppositely and filled with the medium therein, and the cavity walls of the accommodation cavity are provided with a capillary layer. The support and capillary guide columns are provided on the plate body and positioned in the accommodation cavity. Both ends of the support column are connected to the two heat-conducting cavity walls respectively. Both ends of the capillary guide columns are connected to the capillary layer on the two heat-conducting cavity walls respectively. In the cross-section of the capillary guide column, the lengths of the capillary guide columns are greater than their widths, and length directions of part of the capillary guide columns are flow directions of the medium in a gaseous state.

### CROSS-REFERENCE TO RELATED APPLICATION

This application is based on and claims the benefit of priority from Chinese Patent Application No. 2025200081445, filed on Jan. 2, 2025, the entirety of which is incorporated by reference herein.

### TECHNICAL FIELD

The present disclosure relates to a vapor chamber, and in particular, to a high-efficiency vapor chamber.

### BACKGROUND

Electronic devices such as mobile phones usually use vapor chambers for heat dissipation. Some existing vapor chambers each include a plate body, a support column, a heat transfer medium, and a capillary guide column. The accommodation cavity of the plate body is defined by two heat-conducting cavity walls arranged oppositely, and the support column supports the two heat-conducting cavity walls. The cavity wall of the accommodation cavity has a capillary layer, the heat transfer medium is filled in the accommodation cavity, and the capillary guide column is connected between the capillary layers of the two heat-conducting cavity walls. During operation, a heat source contacts the plate body, and gasifies the liquid heat transfer medium in the capillary layer of part of the heat-conducting cavity wall on an evaporation side. Then, the gaseous heat transfer medium flows and disperses in the accommodation cavity and contacts the capillary layer on the heat-conducting cavity wall on a condensation side for liquefaction and heat release. The liquefied heat transfer medium reflows to the evaporation side through the capillary layer. At present, the cross-section of the capillary guide column is in a circular shape, which creates a larger resistance to the flow of gaseous heat transfer fluid, affecting the heat dissipation capacity of the vapor chamber.

### SUMMARY

The present disclosure aims to alleviate at least one of the technical problems existing in the existing technology. To this end, a high-efficiency vapor chamber is proposed, which can reduce the impact of capillary guide column on the fluidity of a heat transfer medium in a gaseous state.

According to an embodiment of the present disclosure, a high-efficiency vapor chamber includes a plate body, a support column, a heat transfer medium, and a capillary guide column. The plate body defines an accommodation cavity defined two heat-conducting cavity walls arranged oppositely, and both of the two heat-conducting cavity walls of the accommodation cavity are provided with a capillary layer. The support column is provided on the plate body and positioned in the accommodation cavity. The support column is positioned between the two heat-conducting cavity walls, and both ends of the support column are connected to the two heat-conducting cavity walls in one-to-one correspondence. The heat transfer medium is provided in the accommodation cavity. A plurality of capillary guide columns are provided on the plate body and positioned in the accommodation cavity, each of the plurality of capillary guide columns is positioned between the two heat-conducting cavity walls, both ends of each of the plurality of capillary guide columns are connected to the capillary layer on the two heat-conducting cavity walls in one-to-one correspondence, each of the plurality of capillary guide columns has its respective cross-section, a length of the respective cross-section of each of the plurality of capillary guide columns is greater than its width, and a length direction of the respective cross-section of at least part of the plurality of capillary guide columns is a flow direction of the heat transfer medium in a gaseous state.

According to an embodiment of the present disclosure, the high-efficiency vapor chamber has at least the following beneficial effects: The length of the cross-section of the capillary guide column is greater than the width of the cross-section of the capillary guide column, and the length direction of the cross-section of the capillary guide column is the flow direction of the heat transfer medium in the gaseous state, so that when the gaseous heat transfer medium flows and disperses in the accommodation cavity, the resistance of the capillary guide column to the gaseous heat transfer medium can be reduced, thereby improving the heat dissipation capacity of the vapor chamber.

According to some embodiments of the present disclosure, the width of the respective cross-section of each of the plurality of capillary guide columns first increases and then decreases in the length direction, and the respective cross-section of each of the plurality of capillary guide columns is in a fusiform shape or elliptic shape.

According to some embodiments of the present disclosure, the plate body is provided with plurality of first plug-in portions each positioned on one of the two heat-conducting cavity walls, each of a plurality of first fitting portions is provided on an end of a respective one of the plurality of capillary guide columns, each of the plurality of first plug-in portions is plug-fitted with a respective one of the plurality of first fitting portions, and the other end of each of the plurality of capillary guide columns abuts against the capillary layer on the other one of the two heat-conducting cavity walls.

According to some embodiments of the present disclosure, each of the plurality of capillary guide columns is in a tapered shape with a smaller end away from the respective first plug-in portion than an opposite end.

According to some embodiments of the present disclosure, all the plurality of capillary guide columns are evenly arranged around a central axis of the accommodation cavity, each of the plurality of capillary guide columns has a respective cross-section, and the length direction of the respective cross-section of each of the plurality of capillary guide columns faces towards the central axis of the accommodation cavity.

According to some embodiments of the present disclosure, a plurality of support columns are provided, each of the plurality of support columns has a respective cross-section, a length of the respective cross-section is greater than its width for each of the plurality of support columns, and a length direction of the respective cross-section of at least part of the plurality of support columns is the flow direction of the heat transfer medium in the gaseous state.

According to some embodiments of the present disclosure, the width of the respective cross-section of each of the plurality of support columns first increases and then decreases in its length direction, and the respective cross-section of each of the plurality of support columns is in a fusiform shape or elliptic shape.

According to some embodiments of the present disclosure, the support column is provided with a second plug-in portion at both ends of the support column, respectively, each of the two heat-conducting cavity walls is provided with a respective second fitting portion, and the two second plug-in portions is plug-fitted one to one with the two second fitting portions.

According to some embodiments of the present disclosure, a plurality of support columns are provided and arranged at intervals from each other.

According to some embodiments of the present disclosure, the plate body includes two side plates, the outer peripheral edges of the two side plates are connected and enclosed to form the accommodation cavity, and the two heat-conducting cavity walls are positioned on the two side plates, respectively.

Additional aspects and advantages of the present disclosure will be set forth in part in the description which follows, and in part will be obvious from the description, or may be learned by practice of the present disclosure.

### BRIEF DESCRIPTION OF DRAWINGS

The above and/or additional aspects and advantages of the present disclosure will become apparent and readily understood from the description of the embodiments in conjunction with the following accompanying drawings, in which:

FIG. 1 is a three-dimensional schematic diagram of a high-efficiency vapor chamber according to an embodiment of the present disclosure;

FIG. 2 is a schematic cross-sectional view in an A-A direction in FIG. 1 according to an embodiment of the present disclosure;

FIG. 3 is a partially schematic enlarged view of section B in FIG. 2 according to an embodiment of the present disclosure;

FIG. 4 is a schematic cross-sectional view of a high-efficiency vapor chamber according to an embodiment of the present disclosure.

### REFERENCE NUMERALS

plate body 100, accommodation cavity 110, heat-conducting cavity wall 111, capillary layer 120, first plug-in portion 130, second fitting portion 140, side plate 150;
support column 200, second plug-in portion 210;
capillary guide column 300, first fitting portion 310;
central axis 400 of accommodation cavity.

### DETAILED DESCRIPTION

Embodiments of the present disclosure will be described in detail below, and examples of the embodiments are shown in the accompanying drawings, where throughout the same or similar reference numerals denote the same or similar elements or elements having the same or similar functions. The following embodiments described with reference to the accompanying drawings are exemplary and serve merely to explain the present disclosure, and should not be construed as limiting the present disclosure.

In the description of the present disclosure, it should be understood that, the orientation or position relation related to the orientation description such as the orientation or position relation indicated by the terms “upper” and “lower” is based on the orientation or position relation shown in the accompanying drawings, merely for ease of description of the present disclosure and simplification for the description, rather than indicating or implying that the device or element referred to must have a specific orientation and be constructed and operated in a specific orientation, which, therefore, shall be construed as limiting the present disclosure.

In the description of the present disclosure, term “a plurality of” refers to two or more. If described, terms such as “first” and “second” are merely for the purpose of distinguishing technical features, and shall not to be construed as indicating or implying relative importance or implicitly indicating the number of technical features indicated or implicitly indicating the precedence relationship of technical features indicated.

In the description of the present disclosure, unless explicitly defined otherwise, providing, installing, connecting and other words should be understood broadly, and a person skilled in the art can reasonably determine the specific meaning of the above words in the present disclosure in conjunction with the specific content of the technical scheme.

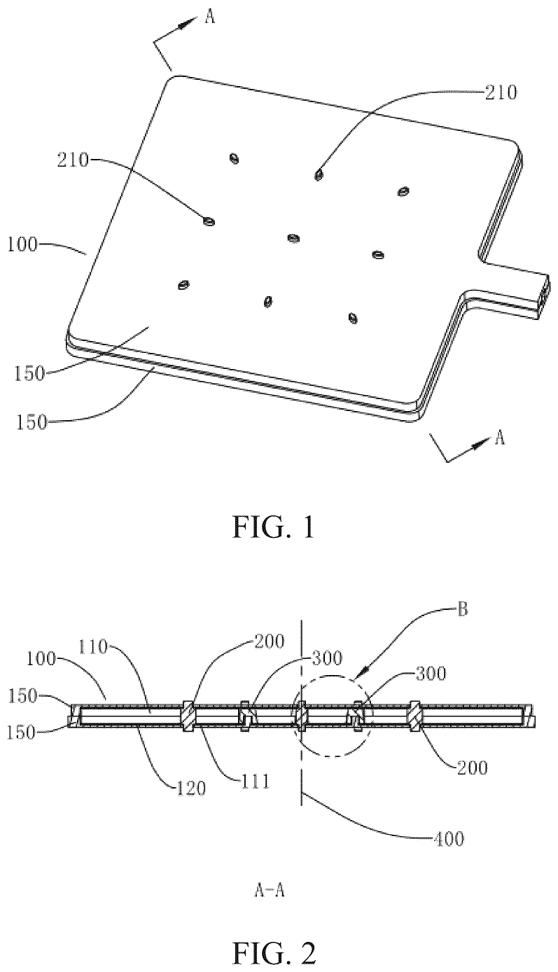

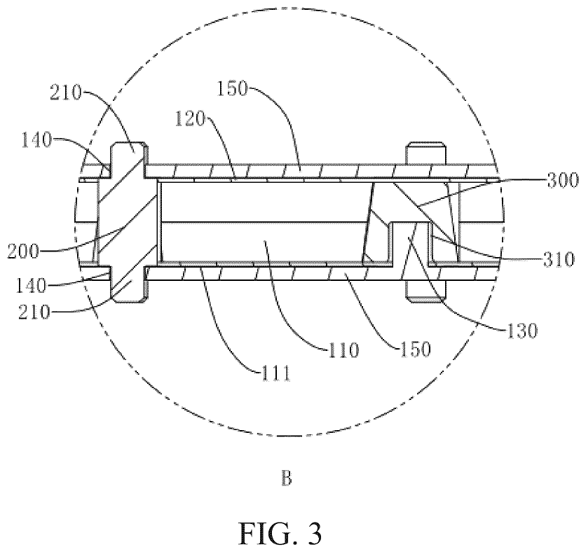

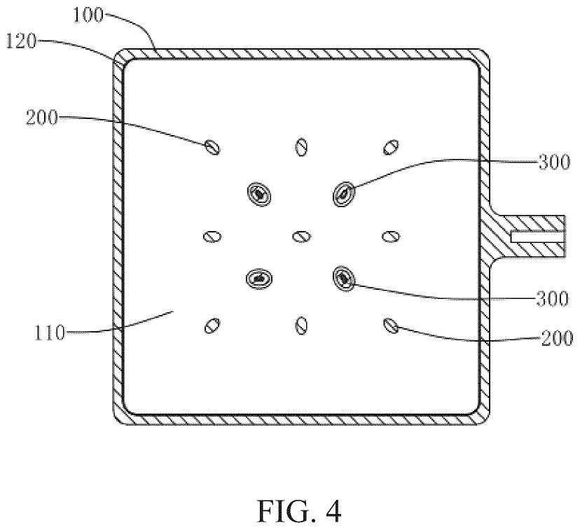

Referring to FIGS. 1 to 4, a high-efficiency vapor chamber according to an embodiment of the present disclosure is shown, including a plate body 100, a support column 200, a heat transfer medium, and capillary guide columns 300. The plate body 100 defines an accommodation cavity 110, which is defined by two heat-conducting cavity walls 111 arranged oppositely, and the heat-conducting cavity walls 111 of the accommodation cavity 110 are provided with a capillary layer 120. The support column 200 is provided on the plate body 100 and positioned in the accommodation cavity 110. The support column 200 is positioned between the two heat-conducting cavity walls 111, and both ends of the support column 200 are connected to the two heat-conducting cavity walls 111 in one-to-one correspondence. The heat transfer medium is provided in the accommodation cavity 110. The capillary guide columns 300 are provided on the plate body 100 and positioned in the accommodation cavity 110. The capillary guide columns 300 are positioned between the two heat-conducting cavity walls 111, and both ends of the capillary guide columns 300 are connected to the capillary layers 120 on the two heat-conducting cavity walls 111 in one-to-one correspondence. The lengths of cross-sections of the capillary guide columns 300 are greater than the widths of the cross-sections of the capillary guide columns 300, and length directions of the cross-sections of part or all of the capillary guide columns 300 are flow directions of the heat transfer medium in a gaseous state.

The length of the cross-section of the capillary guide column 300 is greater than the width the cross-section of the capillary guide column 300, and the length direction of the cross-section of the capillary guide column 300 is the flow direction of the heat transfer medium in the gaseous state, so that when the gaseous heat transfer medium flows and disperses in the accommodation cavity 110, the resistance of the capillary guide column 300 to the gaseous heat transfer medium can be reduced, thereby improving the heat dissipation capacity of the vapor chamber.

Specifically, the support column 200 is configured to support the two heat-conducting cavity walls 111 of the accommodation cavity 110 to reduce the risk of damage to the vapor chamber during production and use. The capillary layers 120 serve to transfer the liquid heat transfer medium.

In an embodiment, the width of the cross-section of the capillary guide column 300 first increases and then decreases in the length direction of the cross-section of the capillary guide column 300, and the cross-section of the capillary guide column 300 is in a fusiform shape or elliptic shape. In the above structure, the cross section of the capillary guide column 300 is approximately streamlined, so that when the gaseous heat transfer medium flows, the resistance of the capillary guide columns 300 to the heat transfer medium can be reduced, thereby further improving the heat dissipation capacity of the vapor chamber. Under the condition that the horizontal cross-sectional areas of the capillary guide columns 300 are the same, the volume of the capillary guide column 300 is reduced.

In an embodiment, the plate body 100 is provided with a first plug-in portion 130 positioned on one of the heat-conducting cavity walls 111. An end of the capillary guide column 300 is provided with a first fitting portion 310. The first plug-in portion 130 is plug-fitted with the first fitting portion 310. The other end of the capillary guide column 300 abuts against the capillary layer 120 on the other heat-conducting cavity wall 111. An end of each of the capillary guide columns 300 is fixed to one of the heat-conducting cavity walls 111 of the plate body 100 through a plug-in fit, and the other end of each of the capillary guide columns 300 abuts against the capillary layer 120 on the other heat-conducting cavity wall 111, so that the capillary guide columns 300 can be mounted and fixed, with a relatively simple installation structure and easy assembly.

Specifically, the first plug-in portion 130 is a plug-in column, the first fitting portion 310 is plug-in hole, and the plug-in column and the plug-in hole are plug-fitted. It can be conceivable that in other embodiments, the first plug-in portion 130 can be a plug-in hole, and the first fitting portion 310 can a plug-in column, which can be configured by those skilled in the art according to actual needs.

Specifically, the first plug-in portion 130 is a plug-in column with a prismatic cross-section, and the first fitting portion 310 is a plug-in hole with an elliptical cross-section, which facilitates the accurate length direction of the cross-section when the capillary guide column 300 is mounted.

In an embodiment, the capillary guide column 300 is in a frustum shape, when it is fixed to the upper heat-conducting cavity wall 111. Alternatively, the capillary guide column 300 is in an obconical shape, when it is fixed to the lower heat-conducting cavity wall 11. Since the end of the capillary guide column 300 proximate to the first plug-in portion 130 is plug-fitted with the first plug-in portion 130, the existence of the first fitting portion 310 reduces the contact area between the end of the capillary guide column 300 proximate to the first plug-in portion 130 and the capillary layer 120. If the difference in the respective contact areas between both ends of the capillary guide column 300 and their corresponding capillary layers 120 is relatively large, an end of the capillary guide column 300 with a smaller contact area with the capillary layer 120 will limit the efficiency thereof in transporting the liquid heat transfer medium. In this regard, the capillary guide column 300 is set in a tapered shape with a small end being the end away from the first plug-in portion 130. At this time, the difference in the respective contact areas between both ends of the capillary guide column 300 and the corresponding capillary layers 120 is relatively small, which is beneficial to improving the efficiency of transporting the liquid heat transfer medium, and can reduce the volume of the capillary guide column 300.

In an embodiment, four capillary guide columns 300 are provided. All the capillary guide columns 300 are evenly arranged around a central axis of the accommodation cavity 110, and the lgenth direction of the cross-section of the capillary guide column 300 faces towards the central axis of the accommodation cavity 110. A heat source is usually small in volume and is placed proximate to the central axis on the evaporation side of the plate body 100, so that the gaseous heat transfer medium in the accommodation cavity 110 flows from the center to the surroundings. Therefore, the above layout of the capillary guide columns 300 can significantly reduce the resistance to liquid heat transfer medium.

It can be conceivable that in other embodiments, the number of the capillary guide column 300 may also be other values, such as three, five or more, which can be specifically configured by those skilled in the art according to actual needs. The length direction of the cross-section of the capillary guide columns 300 can also be arranged in other ways.

In an embodiment, the length of a cross-section of the support columns 200 is greater than the width of the cross-section of the support columns 200, and the length direction of the cross-section of part or all of the support columns 200 is the flow direction of the heat transfer medium in the gaseous state, so that when the gaseous heat transfer medium flows and disperses in the accommodation cavity 110, the resistance of the support column 200 to the gaseous heat transfer medium can be reduced, thereby further improving the heat dissipation capacity of the vapor chamber.

In an embodiment, the width of the cross-section of the support column 200 first increases and then decreases in the length direction of the cross-section of the support column 200, and the cross-section of the support column 200 is in a fusiform shape or elliptic shape. In the above structure, the cross section of the support column 200 is approximately streamlined, so that when the gaseous heat transfer medium flows, the resistance of the support column 200 to the heat transfer medium can be reduced, thereby further improving the heat dissipation capacity of the vapor chamber. In addition, under the condition that the outer surface areas of the support columns 200 are the same, the volume of the support column 200 is reduced.

In an embodiment, the support column 200 is provided with a second plug-in portion 210 both ends of the support column 200, respectively. Each of the two heat-conducting cavity walls 111 provided with a second fitting portion 140. The second plug-in portions 210 is plug-fitted with the second fitting portion 140. The support column 200 is mounted through a plug-in fit, which has a simple structure and is easy to implement. Specifically, the second plug-in portion 210 is a plug-in column, the second fitting portion 140 is a plug-in hole, and both ends of the support column 200 are inserted into the plug-in holes of the two heat-conducting cavity walls 111 through the plug-in columns. It may be conceivable that in other embodiments, the second plug-in portion 210 may also be a plug-in hole, and the corresponding second fitting portion 140 may be a plug-in column, which may be specifically configured by those skilled in the art according to actual needs.

Further, the second plug-in portion 210 is a plug-in column with an elliptical cross-section, and the second fitting portion 140 is a plug-in hole with an elliptical cross-section, which is beneficial to the accurate length direction of the cross-section when the support column 200 are mounted. The plug-in column and the plug-in hole are further hermetically connected by welding.

In an embodiment, a plurality of support columns 200 are provided and arranged at intervals from each other, which is conducive to the relatively uniform support of all parts of the heat-conducting cavity walls 111 and has a good overall support effect. Specifically, the number of the support columns 200 may be two, three, four or more, which may be specifically configured by those skilled in the art according to actual needs.

In an embodiment, the plate body 100 includes two side plates 150. The outer peripheral edges of the two side plates 150 are connected and enclosed to form the accommodation cavity 110. The two heat-conducting cavity walls 111 are respectively positioned on the two side plates 150. The accommodation cavity 110 is formed by connecting the outer peripheral edges of the two side plates 150, making the manufacturing method of the accommodation cavity 110 simple. Specifically, the two outer peripheral edges of the plate body 100 (i.e., the two side plates 150) are hermetically connected by welding.

Specifically, the outer peripheral surface of the support columns 200 also has a capillary layer 120, which can transport the liquid heat transfer medium between the two heat-conducting cavity walls 111.

Specifically, the capillary layers 120 and the capillary structure columns are both of a porous structure formed by sintering copper powder, and can transport the liquid heat transfer medium through a capillary principle.

In the description of this specification, the reference terms such as “one embodiment”, “an embodiment”, “some embodiments”, “illustrative embodiments”, “examples”, “specific examples”, or “some examples” or the like means that specific features, structures, materials or characteristics described in conjunction with the embodiment or example are included in at least one embodiment or example of the present disclosure. In this specification, schematic representations of the above terms do not necessarily refer to the same embodiment or example. Furthermore, the specific features, structures, materials or characteristics described can be combined in any suitable manner in any one or more embodiments or examples.

Although the embodiments of the present disclosure have been shown and described, those of ordinary skill in the art will understand that various changes, modifications, substitutions and variations can be made to these embodiments without departing from the principle and gist of the present disclosure. The scope of the present disclosure is defined by the claims and their equivalents.

What is claimed is:

1. A high-efficiency vapor chamber, comprising:
a plate body provided with an accommodation cavity having two heat-conducting cavity walls arranged oppositely, both of the two heat-conducting cavity walls of the accommodation cavity being provided with a capillary layer;
a support column provided on the plate body and positioned in the accommodation cavity, the support column being positioned between the two heat-conducting cavity walls, and both ends of the support column being connected to the two heat-conducting cavity walls in one-to-one correspondence;
a heat transfer medium provided in the accommodation cavity; and
a plurality of capillary guide columns provided on the plate body and positioned in the accommodation cavity, each of the plurality of capillary guide columns being positioned between the two heat-conducting cavity walls, both ends of each of the plurality of capillary guide columns being connected to the capillary layer on the two heat-conducting cavity walls in one-to-one correspondence, each of the plurality of capillary guide columns having its respective cross-section, a length of the respective cross-section of each of the plurality of capillary guide columns being greater than its width, and a length direction of the respective cross-section of at least part of the plurality of capillary guide columns being a flow direction of the heat transfer medium in a gaseous state.

2. The high-efficiency vapor chamber according to claim 1, wherein the width of the respective cross-section of each of the plurality of capillary guide columns first increases and then decreases in the length direction, and the respective cross-section of each of the plurality of capillary guide columns is in a fusiform shape or elliptic shape.

3. The high-efficiency vapor chamber according to claim 1, wherein the plate body is provided with a plurality of first plug-in portions each positioned on one of the two heat-conducting cavity walls, each of a plurality of first fitting portions is provided on an end of a respective one of the plurality of capillary guide columns, each of the plurality of first plug-in portions is plug-fitted with a respective one of the plurality of first fitting portions, and the other end of each of the plurality of capillary guide columns abuts against the capillary layer on the other one of the two heat-conducting cavity walls.

4. The high-efficiency vapor chamber according to claim 3, wherein each of the plurality of capillary guide columns is in a tapered shape with a smaller end away from a respective first plug-in portion than an opposite end.

5. The high-efficiency vapor chamber according to claim 1, wherein all the plurality of capillary guide columns are evenly arranged around a central axis of the accommodation cavity, each of the plurality of capillary guide columns has a respective cross-section, and the length direction of the respective cross-section of each of the plurality of capillary guide columns faces towards the central axis of the accommodation cavity.

6. The high-efficiency vapor chamber according to claim 1, wherein a plurality of support columns are provided, each of the plurality of support columns has a respective cross-section, a length of the respective cross-section is greater than its width for each of the plurality of support columns, and a length direction of the respective cross-section of at least part of the plurality of support columns is the flow direction of the heat transfer medium in the gaseous state.

7. The high-efficiency vapor chamber according to claim 6, wherein the width of the respective cross-section of each of the plurality of support columns first increases and then decreases in its length direction, and the respective cross-section of each of the plurality of support columns is in a fusiform shape or elliptic shape.

8. The high-efficiency vapor chamber according to claim 1, wherein the support column is provided with a second plug-in portion at both ends of the support column, respectively, each of the two heat-conducting cavity walls is provided with a respective second fitting portion, and the tw second plug-in portions are plug-fitted one to one with the two second fitting portions.

9. The high-efficiency vapor chamber according to claim 1, wherein a plurality of support columns are provided and arranged at intervals from each other.

10. The high-efficiency vapor chamber according to claim 1, wherein the plate body comprises two side plates, the outer peripheral edges of the two side plates are connected and enclosed to form the accommodation cavity, and the two heat-conducting cavity walls are positioned on the two side plates, respectively.
